(19) United States
(12) Patent Application Publication
(10) Pub. No.: US 2013/0335941 A1
(43) Pub. Date: Dec. 19, 2013

(54) TELEVISION AND ELECTRONIC APPARATUS

(71) Applicant: KABUSHIKI KAISHA TOSHIBA, Tokyo (JP)

(72) Inventors: Hiroyuki Minaguchi, Higashimatsuyama-shi (JP); Shinji Hiratomo, Ome-shi (JP); Yasuyuki Suzuki, Tachikawa-shi (JP); Ryosuke Saito, Koganei-shi (JP)

(73) Assignee: KABUSHIKI KAISHA TOSHIBA, Tokyo (JP)

(21) Appl. No.: 13/801,939

(22) Filed: Mar. 13, 2013

(30) Foreign Application Priority Data
Jun. 14, 2012 (JP) 2012-134974

(51) Int. Cl. H05K 9/00

(52) U.S. Cl. CPC H05K 9/002
USPC 361/818

(57) ABSTRACT

According to one embodiment, an electronic apparatus includes a housing, a component in the housing, an antenna in the housing, and an electrically conductive wall in the housing. The component is configured to emit electromagnetic noise. The wall is between the component and the antenna.

### CROSS-REFERENCE TO RELATED APPLICATIONS

This application is based upon and claims the benefit of priority from Japanese Patent Application No. 2012-134974, filed Jun. 14, 2012, the entire contents of which are incorporated herein by reference.

### FIELD

Embodiments described herein relate generally to electronic apparatuses including televisions.

### BACKGROUND

Electronic apparatuses with an antenna have been provided.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary front view of a television according to a first embodiment;

FIG. 2 is an exemplary rear view of the television illustrated in FIG. 1;

FIG. 3 is an exemplary perspective view of an electronic apparatus according to a second embodiment;

FIG. 4 is an exemplary plan view illustrating an inner portion of a first housing of the electronic apparatus illustrated in FIG. 3;

FIG. 5 is an exemplary perspective view illustrating a shielding structure illustrated in FIG. 4;

FIG. 6 is an exemplary cross-sectional view illustrating the shielding structure illustrated in FIG. 4;

FIG. 7 is an exemplary cross-sectional view taken along the line F7-F7, of the shielding structure illustrated in FIG. 6;

FIG. 8 is an exemplary perspective view illustrating a lower surface of the electronic apparatus illustrated in FIG. 3;

FIG. 9 is an exemplary cross-sectional view of an electronic apparatus according to a first modification of the second embodiment;

FIG. 10 is an exemplary cross-sectional view of an electronic apparatus according to a second modification of the second embodiment;

FIG. 11 is an exemplary perspective view of an electronic apparatus according to a third embodiment;

FIG. 12 is an exemplary exploded perspective view of the electronic apparatus illustrated in FIG. 11;

FIG. 13 is an exemplary plan view illustrating an inner portion of the electronic apparatus illustrated in FIG. 11;

FIG. 14 is an exemplary perspective view illustrating a portion of a middle plate illustrated in FIG. 13 in an enlarged scale;

FIG. 15 is an exemplary cross-sectional view taken along the line F15-F15 of a housing illustrated in FIG. 13; and

FIG. 16 is an exemplary plan view illustrating an inner portion of an electronic apparatus according to a modification of the third embodiment.

### DETAILED DESCRIPTION

Various embodiments will be described hereinafter with reference to the accompanying drawings.

In general, according to one embodiment, an electronic apparatus comprises a housing, a component in the housing, an antenna in the housing, and an electrically conductive wall in the housing. The component is configured to emit electromagnetic noise. The wall is between the component and the antenna.

Hereinafter, embodiments will be described with reference to the accompanying drawings. In this specification, some components are expressed by two or more terms. Those terms are just examples. Those components may be further expressed by another or other terms. And the other components which are not expressed by two or more terms may be expressed by another or other terms.

### First Embodiment

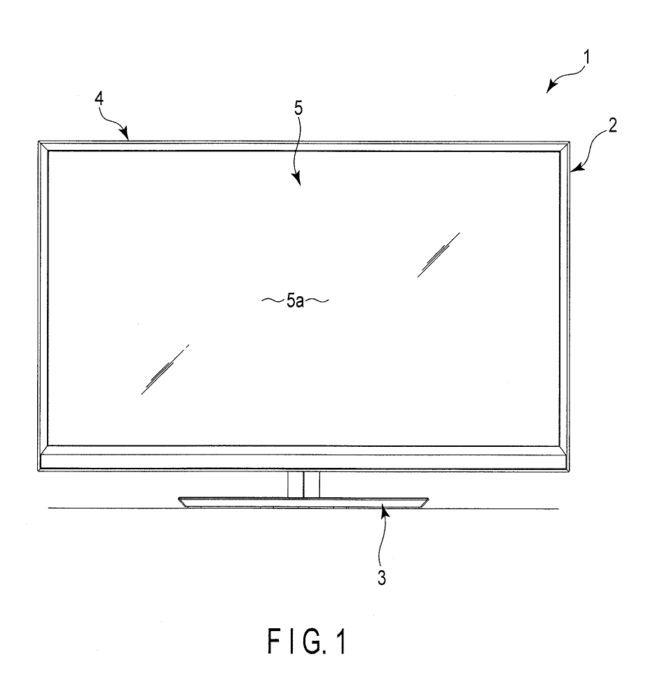

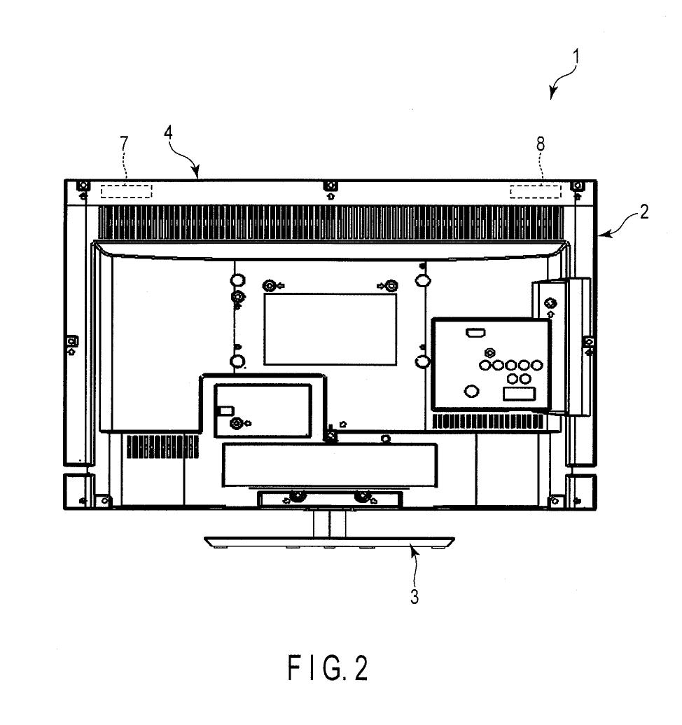

FIGS. 1 and 2 illustrate a television 1 according to a first embodiment. The television 1 is an example of an “electronic apparatus.” The television 1 includes a display unit 2 and a stand 3 (i.e., a supporting portion or a table) that supports the display unit 2.

As illustrated in FIG. 1, the display unit 2 includes a flat box-like housing 4 and a display 5 that is accommodated in the housing 4. An opening through which a display screen 5a of the display 5 is exposed is formed on a front wall of the housing 4.

As illustrated in FIG. 2, antennas 7 and 8 are accommodated in the housing 4. A shielding structure for blocking electromagnetic interference is provided around the antennas 7 and 8. The details of the shielding structure are approximately the same as the structure provided to an electronic apparatus 11 according to a second embodiment. Therefore, the electronic apparatus 11 according to the second embodiment will be described in detail, and detailed description of the television 1 will not be provided. Configurations having the same or similar functions as those of the first embodiment will be denoted by the same reference numerals.

### Second Embodiment

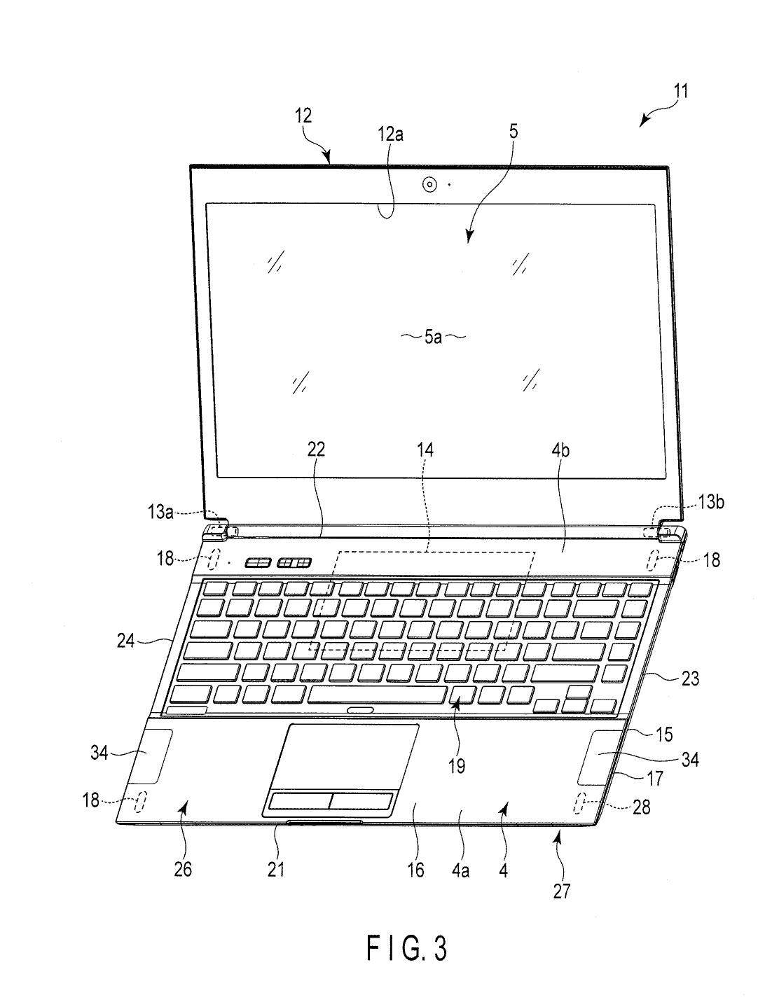

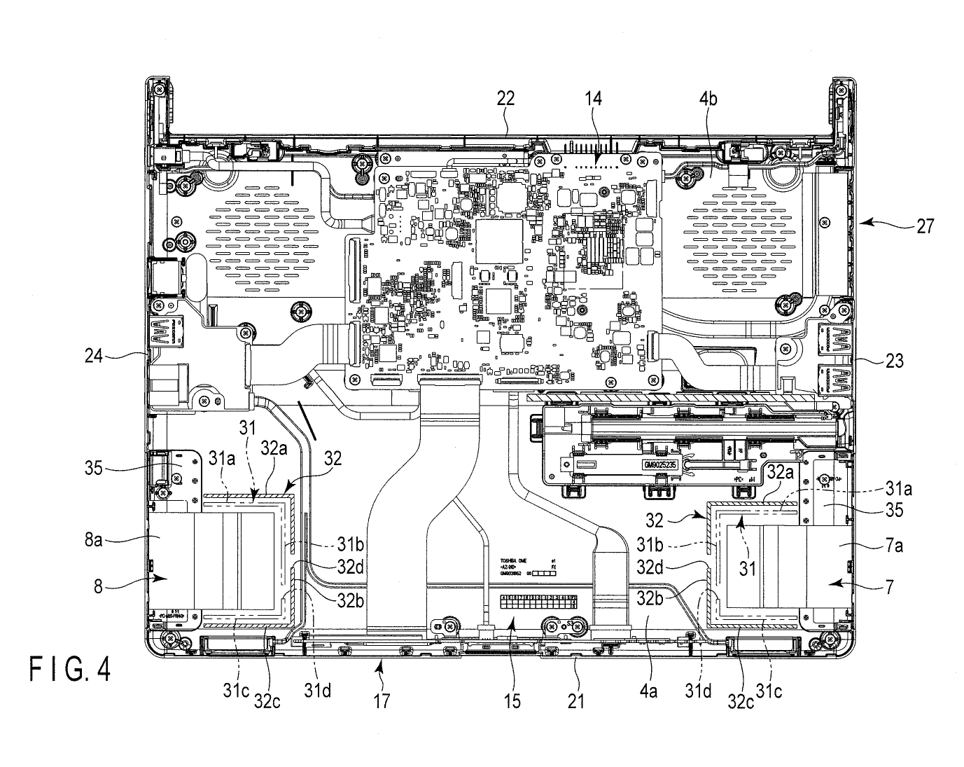

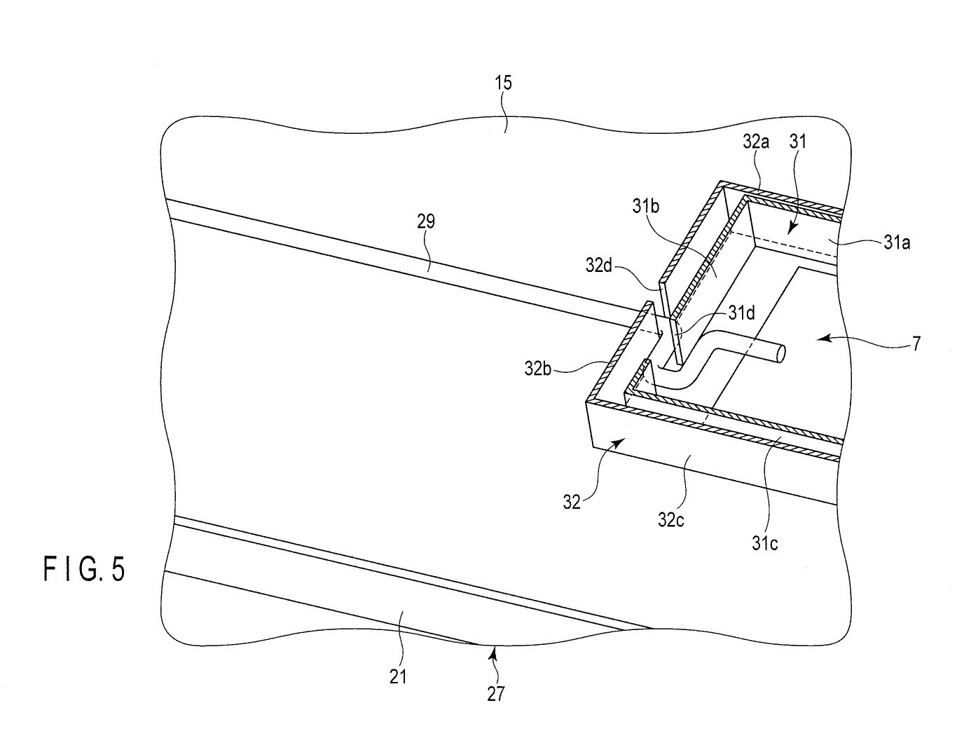

Next, the electronic apparatus 11 according to the second embodiment will be described with reference to FIGS. 4 to 10. As illustrated in FIG. 3, the electronic apparatus 11 according to the embodiment is a notebook-type portable computer (i.e., note PC), for example. Electronic apparatuses to which the embodiment can be applied are not limited to the above examples. The structure according to the embodiment can be broadly applied to various electronic apparatuses such as, for example, a slate-type portable computer, a television, a mobile phone (including a smart phone), or a game machine.

As illustrated in FIG. 3, the electronic apparatus 11 includes a first housing 4, a second housing 12, and hinges 13a and 13b. The first housing 4 is a main housing, for example. A circuit board 14 serving as a main board, for example, is accommodated in the first housing 4. The first housing 4 includes a lower wall 15 (i.e., a bottom wall or a first wall), an upper wall 16 (i.e., a second wall), and a circumferential wall 17 (i.e., a side wall or a third wall), and has a flat box-like shape.

The lower wall 15 faces a table surface (i.e., a mounting surface, an outer surface, or an outer mounting surface) when the electronic apparatus 11 is placed on a table, for example. A plurality of legs 18 (i.e., supporting portions), for example, is provided on the lower wall 15. When the electronic apparatus 11 is placed on the table, the legs 18 make contact with the table surface and support the electronic apparatus 11.

The upper wall 16 is positioned on a side opposite to the lower wall 15. The upper wall 16 extends approximately in parallel with the lower wall 15, for example. An input portion 19 (i.e., an input receiving portion), for example, is provided on the upper wall 16. A keyboard is an example of the input portion 19. The input portion 19 is not limited to the keyboard but may be a touch panel (i.e., a touch sensor), for example, or other input devices. The circumferential wall 17 extends in a direction crossing (e.g., substantially orthogonal to) the upper wall 16 and the lower wall 15 and connects a peripheral portion of the upper wall 16 and a peripheral portion of the upper wall 15.

The first housing 4 includes a first end portion 4a and a second end portion 4b. The first end portion 4a is a front end portion, for example. The second end portion 4b is a rear end portion, for example, and is positioned on a side opposite to the first end portion 4a. The hinges 13a and 13b are connected to the second end portion 4b. Herein, the side closer to the user as seen from the user is defined as “front” and the side further from the user is defined as “rear” based on the posture of the electronic apparatus placed on the mounting surface. Moreover, the directions left and right are defined as seen from the user.

The circumferential wall 17 includes a front wall 21, a rear wall 22, a first side wall 23 (e.g., a right side wall), and a second side wall 24 (e.g., a left side wall). The front wall 21 is positioned at the first end portion 4a of the first housing 4 and extends in the longitudinal direction of the first housing 4. The rear wall 22 is positioned on a side opposite to the front wall 21 and extends substantially in parallel with the front wall 21. The first side wall 23 and the second side wall 24 extend in a direction crossing (e.g., substantially orthogonal to) the front wall 21 and the rear wall 22 and connect the front wall 21 and the rear wall 22.

The second housing 12 is a display housing, for example. A display 5 (i.e., a display device, display module, or a unit) is accommodated in the second housing 12. The display 5 includes the display screen 5a. An opening 12a through which the display screen 5a is exposed is formed on the front wall of the second housing 12.

The hinges 13a and 13b rotatably (i.e., openably) connect the end portion of the first housing 4 and the end portion of the second housing 12. In this way, the electronic apparatus 11 can be opened (i.e., folded). The electronic apparatus 11 can be deformed into a first state where the first housing 4 and the second housing 12 overlap each other and a second state where the first housing 4 and the second housing 12 are open so that the display screen 5a is exposed to the outside.

Next, the structure of the first housing 4 (hereinafter referred to as the housing 4) will be described in detail.

As illustrated in FIG. 3, the housing 4 includes an upper cover 26 (i.e., a mask, a first cover, a first member, or a first component) and a lower cover 27 (i.e., a base, a second cover, a second member, or a second component). The lower cover 27 includes a lower wall 15 and a circumferential wall 17 and has a bowl shape of which the upper side is open. On the other hand, the upper cover 26 includes an upper wall 16.

The upper cover 26 and the lower cover 27 are combined to form an example of the housing 4. In the embodiment, the upper cover 26 and the lower cover 27 are made from metal and have electrically conductive properties. Any one of the upper cover 26 and the lower cover 27 or both may be made from a synthetic resin. The upper cover 26 or the lower cover 27 that is made from a synthetic resin may be provided with electrically conductive properties by means of conductive coating, plating, or the like as necessary.

As illustrated in FIG. 4, a circuit board 14, a first antenna 7, and a second antenna 8 are accommodated in the housing 4. The circuit board 14 is an example of a “component (i.e., member) that emits electromagnetic noise. The “component (member) that emits electromagnetic noise” is not limited to the circuit board 14 but appropriately includes various modules and electronic components that are accommodated in the housing 4.

As illustrated in FIG. 4, the circuit board 14 is provided at a position closer to the rear wall 22 than to the front wall 21. On the other hand, the first antenna 7 and the second antenna 8 are provided at a position closer to the front wall 21 than to the rear wall 22. The first antenna 7 and the second antenna 8 are provided at the left and right ends of the housing 4, respectively.

The first antenna 7 is positioned close to the first side wall 23. The second antenna 8 is positioned close to the second side wall 24. More specifically, the first antenna 7 is positioned at a first corner of the right front end portion of the housing 4. The second antenna 8 is positioned at a second corner of the left front end portion of the housing 4. The first antenna 7 and the second antenna 8 each include a cable 29 (i.e., an antenna cable). The cable 29 is electrically connected to the circuit board 14, for example.

In the embodiment, a shielding structure that blocks electromagnetic noise (i.e., electromagnetic interference) is provided around each of the first antenna 7 and the second antenna 8. In this example, the shielding structure around the first antenna 7 will be described as a representative example. The shielding structure around the second antenna 8 has substantially the same configuration and function as those of the shielding structure around the first antenna 7.

As illustrated in FIGS. 4 to 7, the upper cover 26 includes a first rib 31 (i.e., a first wall, a first wall, a first projection, a first shielding portion, or a first shield). The first rib 31 is a portion of the upper cover 26 and is integrated with the upper cover 26. The first rib 31 according to the embodiment is made from metal and has electrically conductive properties. The first rib 31 may be made from a synthetic resin and may have electrically conductive properties by means of metal coating, plating, or the like. The first rib 31 and the upper cover 26 are connected to the ground and have the ground potential.

The first rib 31 extends (i.e., projects) in the thickness direction of the housing 4 from an inner surface of the upper cover 26 (i.e., the upper wall 16) to the lower cover 27 (i.e., the lower wall 15). The first rib 31 is positioned between the circuit board 14 and the first antenna 7 (hereinafter referred to as the antenna 7). The first rib 31 is provided along a portion of the outer shape of the antenna 7 and faces the antenna 7 from a plurality of directions (e.g., three directions).

Specifically, the first rib 31 includes a first portion 31a, a second portion 31b, and a third portion 31c. The first portion 31a extends in the longitudinal direction of the housing 4. The first portion 31a faces the circuit board 14. Herein, the expression “A faces B” is used to mean “A faces in a direction toward B. That is, the expression “A faces B” also includes a case where A directly faces B and a case where A faces B with C interposed therebetween.

The first portion 31a is positioned between the circuit board 14 and the antenna 7. In other words, the circuit board 14 is positioned between the first portion 31a and the rear wall 22. The antenna 7 is positioned between the first portion 31a and the front wall 21.

The second portion 31b extends in a direction crossing (e.g., substantially orthogonal to) the first portion 31a. The second portion 31b does not face the circuit board 14. The second portion 31b faces the antenna 7 from a side opposite to the first side wall 23. In other words, the antenna 7 is positioned between the second portion 31b and the first side wall 23.

A first guiding portion 31d (i.e., first pass) through which the cable 29 passes is provided in the second portion 31b. The first guiding portion 31d is open in a direction where the first guiding portion 31d does not face the circuit board 14 (i.e., a component that emits electromagnetic noise). A slit is an example of the first guiding portion 31d. This slit is open to a lower end portion of the first rib 31, for example. The first guiding portion 31d may be a hole or a cut-out.

The third portion 31c extends substantially in parallel with the first portion 31a. The third portion 31c faces the antenna 7 from a side opposite to the first portion 31a. In other words, the antenna 7 is positioned between the first portion 31a and the third portion 31c. With the above-described configuration, the first rib 31 faces the antenna 7 from three directions. The antenna 7 transmits and receives electromagnetic waves from the remaining one direction.

The first rib 31 may be formed on a middle plate 45 according to a third embodiment instead of the upper cover 26. The middle plate 45 is an example of a “member that is accommodated in a housing and covers at least a portion of a member that emits electromagnetic noise and at least a portion of an antenna” and is also an example of a “member that is accommodated in a housing and faces a member that emits electromagnetic noise from a thickness direction of the housing.”

On the other hand, as illustrated in FIGS. 4 to 7, the lower cover 27 includes a second rib 32 (i.e., a second wall, a second wall, a second projection, a second shielding portion, or a second shield). The second rib 32 is a portion of the lower cover 27 and is integrated with the lower cover 27. The second rib 32 according to the embodiment is made from metal and has electrically conductive properties. The second rib 32 may be made from a synthetic resin and may have electrically conductive properties by means of metal coating, plating, or the like. The second rib 32 and the lower cover 27 are connected to the ground and have the ground potential.

The second rib 32 extends (i.e., projects) in the thickness direction of the housing 4 from an inner surface of the lower cover 27 (i.e., the lower wall 15) to the upper cover 26 (i.e., the upper wall 16). The second rib 32 is positioned between the circuit board 14 and the antenna 7. The second rib 32 is provided along a portion of the outer shape of the antenna 7 and faces the antenna 7 from a plurality of directions (e.g., three directions).

As illustrated in FIGS. 4 to 7, in the embodiment, the second rib 32 is formed on the outer side of the first rib 31 and surrounds the outer side of the first rib 31 from three directions. The second rib 32 is positioned between the circuit board 14 and the first rib 31. The second rib 32 may be formed on the inner side of the first rib 31 and may be positioned between the first rib 31 and the antenna 7.

Specifically, the second rib 32 includes a first portion 32a, a second portion 32b, and a third portion 32c. The first portion 32a extends in the longitudinal direction of the housing 4. The first portion 32a faces the circuit board 14 and faces the first portion 31a of the first rib 31. The first portion 32a is positioned between the circuit board 14 and the first rib 31.

The second portion 32b extends in a direction crossing (e.g., substantially orthogonal to) the first portion 32a. The second portion 32b does not face the circuit board 14. The second portion 32b faces the second portion 31b of the first rib 31. A second guiding portion 32d (i.e., second pass) through which the cable 29 passes is provided in the second portion 32b. The second guiding portion 32d is open in a direction where the second guiding portion 32d does not face the circuit board 14 (i.e., the member that emits electromagnetic noise). A slit is an example of the second guiding portion 32d. This slit is open to a lower end portion of the second rib 32, for example. The second guiding portion 32d may be a hole or a cut-out.

As illustrated in FIGS. 4 to 6, the first guiding portion 31d and the second guiding portion 32d are formed at mutually shifted positions (e.g., offset positions). That is, when the upper cover 26 and the lower cover 27 are combined, the first guiding portion 31d and the second guiding portion 32d are not positioned on a straight line but the first guiding portion 31d and the second guiding portion 32d are disposed so as to be shifted in a zigzag form. In other words, the first guiding portion 31d is covered by the second rib 32. The second guiding portion 32d is covered by the first rib 31.

The third portion 32c extends substantially in parallel with the first portion 32a. The third portion 32c faces the third portion 31c of the first rib 31. With the above-described configuration, the second rib 32 faces the antenna 7 from three directions. In this way, a double shielding structure formed by the first rib 31 and the second rib 32 is formed around the antenna 7.

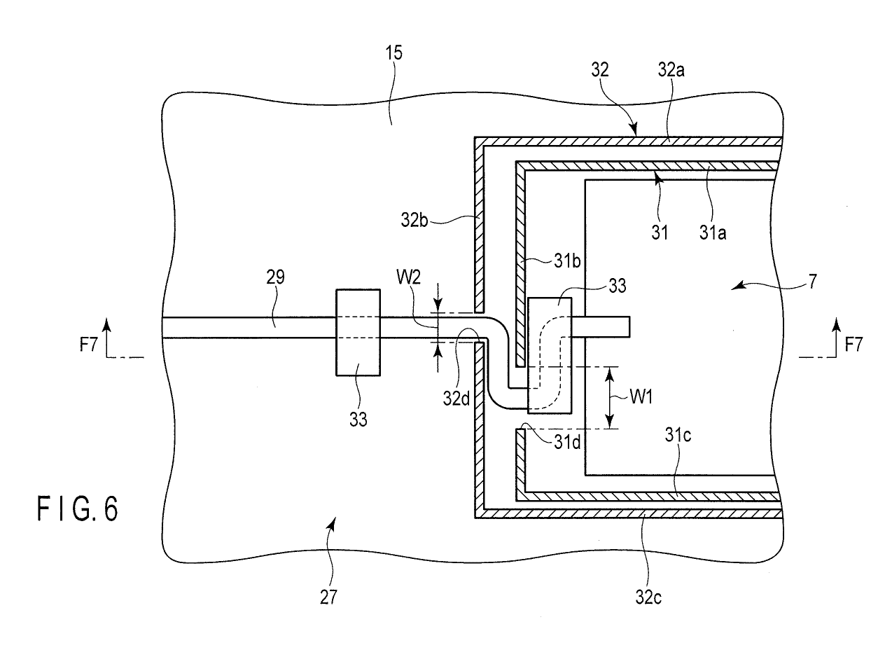

As illustrated in FIG. 6, a gap between the second portion 31b of the first rib 31 and the second portion 32b of the second rib 32 is greater than a diameter of the cable 29. The cable 29 extended from the antenna 7 passes through the first guiding portion 31d, extends along the gap between the second portion 31b of the first rib 31 and the second portion 32b of the second rib 32, passes through the second guiding portion 32d, and extends toward the circuit board 14.

As illustrated in FIG. 6, the antenna 7 and the cable 29 are attached to the lower wall 15. The cable 29 is fixed to the lower wall 15 by a fixing member 33 such as a tape, for example. When the electronic apparatus 11 is assembled, the cable 29 passes through the second guiding portion 32d and fixed to the housing 4 (e.g., the lower cover 27) before the upper cover 26 and the lower cover 27 are combined.

After the cable 29 is fixed to the housing 4 (e.g., the lower cover 27), the upper cover 26 and the lower cover 27 are combined, and the cable 29 passes through the first guiding portion 31d. In the embodiment, a width W1 of the first guiding portion 31d is greater than a width W2 of the second guiding portion 32d. In this way, when the upper cover 26 and the lower cover 27 are combined, the cable 29 can easily enter into the first guiding portion 31d.

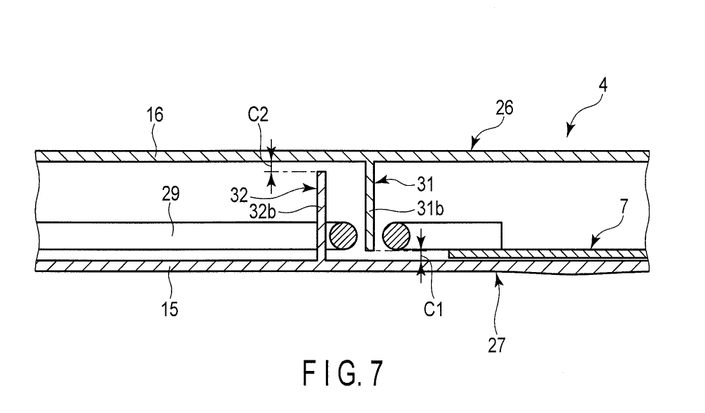

As illustrated in FIG. 7, the first rib 31 has a height such that the first rib 31 does not interfere with the lower cover 27 (i.e., the lower wall 15). Thus, a gap C1 is secured between the distal end of the first rib 31 and the lower cover 27 (i.e., the lower wall 15). An example of the gap C1 is smaller than the diameter of the cable 29.

Similarly, the second rib 32 has a height such that the second rib 32 does not interfere with the upper cover 26 (i.e., the upper wall 16). Thus, a gap C2 is secured between the distal end of the second rib 32 and the upper cover 26 (i.e., the upper wall 16). An example of the gap C2 is smaller than the diameter of the cable 29.

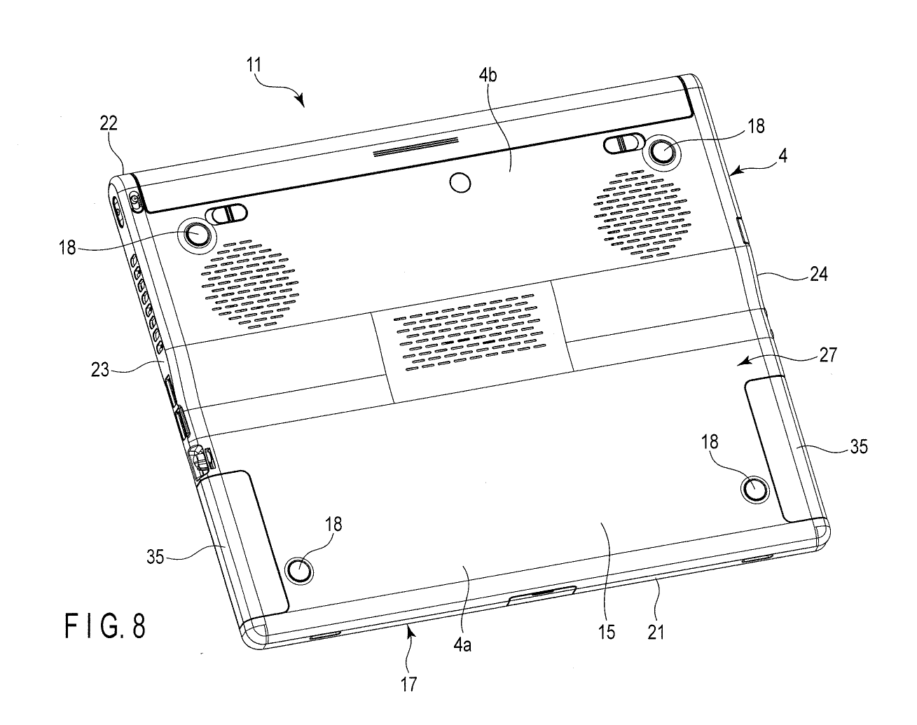

As illustrated in FIGS. 3 and 8, an end portion of the upper cover 26 includes a first antenna cover 34. The first antenna cover 34 is made from a synthetic resin and faces element portions 7a and 8a of the antennas 7 and 8. Similarly, an end portion of the lower cover 27 includes a second antenna cover 35. The second antenna cover 35 is made from a synthetic resin and faces the element portions 7a and 8a of the antennas 7 and 8. The antennas 7 and 8 transmit and receive electromagnetic waves to and from the outside through the antenna covers 34 and 35.

According to such a configuration, it is possible to improve the usability of the electronic apparatus 11. For example, electromagnetic noise (i.e., electromagnetic interference) emitted from a circuit board has a bad influence on the transmission and reception characteristics of an antenna. As a method of preventing the electromagnetic noise, an electrically conductive gasket may be disposed around the antenna and compressed between an upper cover and a lower cover that have electrically conductive properties to reinforce the ground so that electromagnetic interference can be blocked.

However, in assembling of the housing, when the gasket is compressed, the housing receives repulsive force of the gasket so that the housing is screwed in a misaligned state. Thus, in a finished electronic apparatus, since a plurality of legs does not make contact with a mounting surface in a uniform manner, a stability failure such as rattling legs may occur in the electronic apparatus. Further, the amount of compressing and a method of compressing the gasket may slightly fluctuate in each assembling and disassembling, the electromagnetic interference blocking property is not very stable.

On the other hand, the structure according to the embodiment provides a structure that blocks electromagnetic interference without using the gasket. For example, the electronic apparatus 11 according to the embodiment includes a component (e.g., the circuit board 14) that emits electromagnetic noise, the antenna 7 that is accommodated in the housing 4, and a electrically conductive wall (e.g., the first rib 31 or the second rib 32) that is a portion of the housing 4 or a member that is accommodated in the housing 4 and faces the component in the thickness direction of the housing 4, and is positioned between the component and the antenna 7.

According to such a configuration, since part of the electromagnetic noise propagating from the component toward the antenna 7 is blocked by the wall, it is possible to suppress a decrease of the performance of the antenna 7. In this way, it is possible to provide a shielding structure that does not use a gasket.

If the gasket can be eliminated, when the housing 4 is assembled, it is possible to suppress the housing 4 from being misaligned, deformed, or bent in response to the repulsive force from the gasket. As a result, it is possible to assemble the housing 4 in a stable state and prevent the occurrence of ratting of legs. In this way, since the product quality is improved, and rattling of legs, for example, does not occur, the usability of the electronic apparatus is improved.

Further, when the housing is assembled, since components in the housing may not be floated and tilted in response to the repulsive force of the gasket, the assembling workability is stabilized and the working efficiency can be improved. In this way, it is possible to decrease the cost of the product.

Further, according to the above-described configuration, since the shielding structure is realized by the wall, the blocking effect is stabilized as compared to the gasket method in which the blocking effect varies depending on the amount of compressing and the compressing method. In this way, it is possible to stabilize the performance of the antenna.

Further, according to the above-described configuration, since the gasket can be eliminated, it is possible to decrease the cost of the components. Moreover, since the wall can be provided by forming an erected rib on the housing, the cost of the housing may remain substantially the same.

In the embodiment, the electronic apparatus 11 includes a component (e.g., the circuit board 14) that emits electromagnetic noise, the antenna 7 that is accommodated in the housing 4, the first conductive rib 31 that is a portion of the housing 4 or a member that is accommodated in the housing 4, covers at least a portion of the component and at least a portion of the antenna 7, extends in the thickness direction of the housing 4, and is positioned between the component and the antenna 7, and the second conductive rib 32 that extends in the thickness direction of the housing 4 from an inner surface of the housing 4 and is positioned between the component and the first rib 31 or between the first rib 31 and the antenna 7.

According to such a configuration, since a double shielding structure is realized by the first rib 31 and the second rib 32, the performance of the antenna is further stabilized.

In the embodiment, the first rib 31 is provided with the first guiding portion 31d through which the cable 29 passes. According to such a configuration, the antenna can be shielded by the first rib 31 except the portion through which the cable 29 passes, and the antenna 7 performance is further stabilized.

In the embodiment, the first rib 31 includes the first portion 31a that is positioned between the component and the antenna 7 and the second portion 31b that extends in a direction crossing the first portion 31a and does not face the component. The first guiding portion 31d is formed in the second portion 31b. According to such a configuration, the first guiding portion 31d does not face the component. Thus, the electromagnetic noise is more rarely transmitted to the antenna 7, and the performance of the antenna 7 is further stabilized.

In the embodiment, the second rib 32 is provided with the second guiding portion 32d through which the cable 29 passes. The first guiding portion 31d and the second guiding portion 32d are formed at mutually shifted positions. According to such a configuration, the electromagnetic noise is more rarely transmitted to the antenna 7, and the performance of the antenna 7 is further stabilized.

In the embodiment, the cable 29 is set in through the first guiding portion 31d after the cable 29 is set in through the second guiding portion 32d and attached to the housing 4. The width W1 of the first guiding portion 31d is greater than the width W2 of the second guiding portion 32d. According to such a configuration, when the housing 4 is assembled, the cable 29 is rarely pinched between the first rib 31 and the lower cover 27. In this way, it is possible to protect the cable 29.

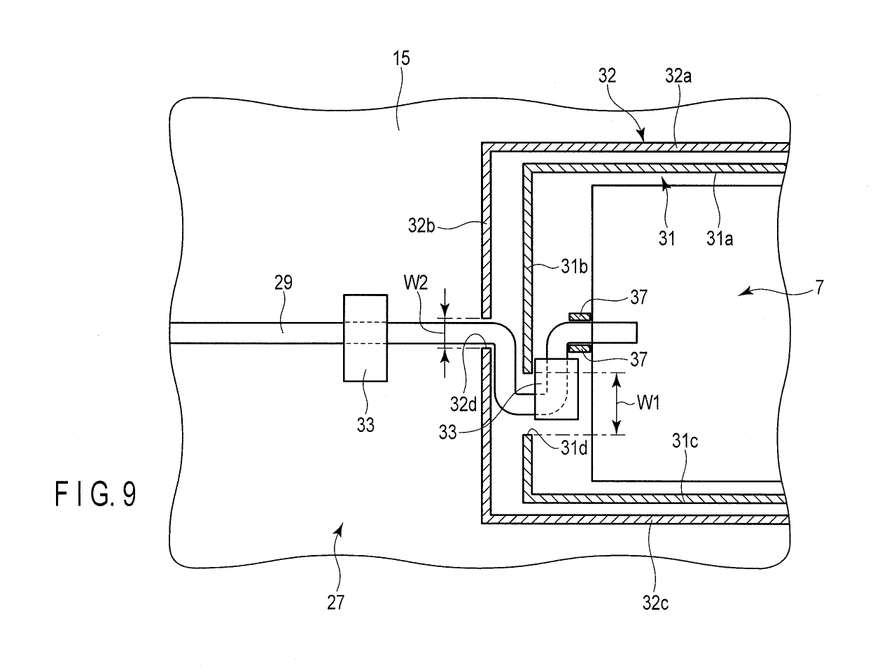

Next, a first modification of the embodiment will be described with reference to FIG. 9.

As illustrated in FIG. 9, in the first modification, a cable supporting portion 37 is formed on the lower cover 27. The cable supporting portion 37 is a projection (e.g., rib) that protrudes from the inner surface of the lower wall 15, for example. The cable 29 is supported by the cable supporting portion 37, and the position and direction thereof are fixed. If the cable 29 is supported with the position and direction thereof stabilized, the possibility that the cable 29 is pinched between the first rib 31 and the lower cover 27 when the housing 4 is assembled further decreases.

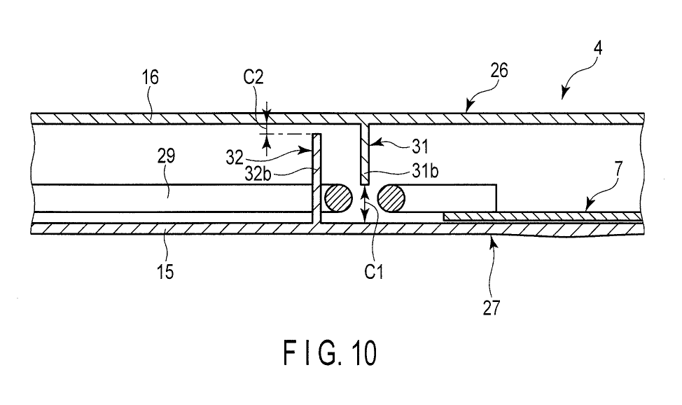

Next, a second modification of the embodiment will be described with reference to FIG. 10.

As illustrated in FIG. 10, in the second modification, the gap C1 between the distal end of the first rib 31 and the lower cover 27 (i.e., the lower wall 15) is greater than the diameter of the cable 29. According to such a configuration, the possibility that the cable 29 is pinched between the first rib 31 and the lower cover 27 when the housing 4 is assembled further decreases.

### Third Embodiment

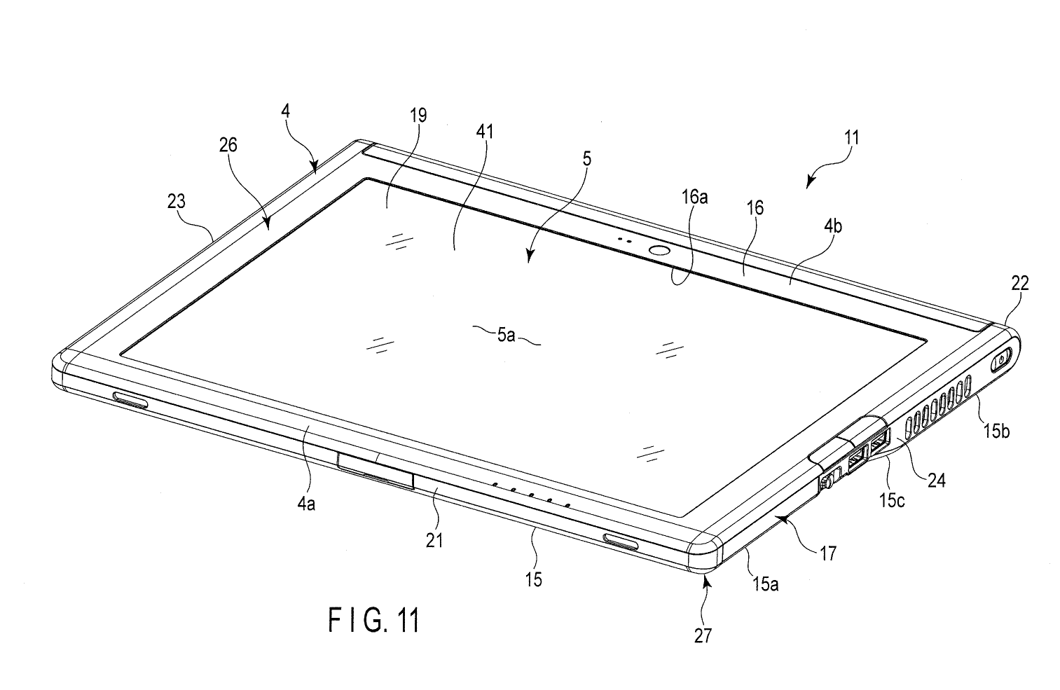

Next, an electronic apparatus 11 according to the third embodiment will be described with reference to FIGS. 11 to 16. In the third embodiment, configurations having the same or similar functions as those of the first and second embodiments will be denoted by the same reference numerals, and description thereof will not be provided. In addition, configurations other than the following configurations are the same as those of the second embodiment.

As illustrated in FIG. 11, the electronic apparatus 11 according to the embodiment is a slate-type portable computer which is so-called a tablet terminal. Electronic apparatuses to which the embodiment can be applied are not limited to the above examples. The structure according to the embodiment can be broadly applied to various electronic apparatuses such as, for example, a notebook-type portable computer, a television, a mobile phone (including a smart phone), or a game machine.

As illustrated in FIG. 11, the electronic apparatus 11 includes a housing 4. The housing 4 has a flat box-like shape, for example. The electronic apparatus 11 is used in a state of being placed on a table surface (i.e., a mounting surface, an outer surface, or an outer mounting surface), for example. Moreover, the electronic apparatus 11 may be used in a state of being held by a hand.

A display 5 is accommodated in the housing 4. The display 5 includes a display screen 5a. A touch panel 41 (i.e., a touch sensor) is formed on the display screen 5a. The touch panel 41 covers the display screen 5a and is integrated with the display screen 5a. In this way, the electronic apparatus 11 can receive the input from the user. The touch panel 41 is an example of an “input portion (i.e., an input receiving portion).”

As illustrated in FIG. 11, the housing 4 includes a lower wall 15 (i.e., a bottom wall or a first wall), an upper wall 16 (i.e., a second wall), and a circumferential wall 17 (i.e., a side wall or a third wall). The upper wall 16 expands substantially in parallel with the display screen 5a and is formed in a planar form. The upper wall 16 extends over a first end portion 4a and a second end portion 4b. The upper wall 16 includes an opening 16a through which the display screen 5a is exposed to the outside. The opening 16a is positioned between the first end portion 4a and the second end portion 4b.

The lower wall 15 is positioned on a side opposite to the upper wall 16. The lower wall 15 includes a first lower wall 15a (i.e., a first portion), a second lower wall 15b (i.e., a second portion), and a slope portion 15c (i.e., a third portion). The first lower wall 15a, the second lower wall 15b, and the slope portion 15c extend over the entire width of the housing 4 in the longitudinal direction (e.g., width direction) of the housing 4.

The first lower wall 15a is adjacent to the first end portion 4a of the housing 4 and constitutes a portion of the first end portion 4a. The first lower wall 15a extends substantially in parallel with the display screen 5a. The first lower wall 15a includes a plurality of legs 18 (i.e., supporting portions) and is supported by the legs 18.

The second lower wall 15b is adjacent to the second end portion 4b of the housing 4 and constitutes a portion of the second end portion 4b. The second lower wall 15b extends substantially in parallel with the display screen 5a. The distance between the second lower wall 15b and the display screen 5a is greater than the distance between the first lower wall 15a and the display screen. The second lower wall 15b includes a plurality of legs 18 (i.e., supporting portions) and is supported by the legs 18.

The slope portion 15c (e.g., a sloped wall) is positioned between the first lower wall 15a and the second lower wall 15b and extends over the first lower wall 15a and the second lower wall 15b. The slope portion 15c connects the rear end portion of the first lower wall 15a and the front end portion of the second lower wall 15b. The slope portion 15c is inclined with respect to the display screen 5a.

The slope portion 15c is inclined away from the display screen 5a as the slope portion 15c advances from the first lower wall 15a toward the second lower wall 15b, and smoothly connects a step between the first lower wall 15a and the second lower wall 15b. With such a configuration, in a state where first legs 43a and second legs 43b are placed (i.e., in contact with) on the mounting surface, the upper wall 16 (i.e., the display screen 5a) is inclined to be raised backward with respect to the mounting surface.

As illustrated in FIG. 11, the circumferential wall 17 extends in a direction crossing (e.g., substantially orthogonal to) the upper wall 16 and the lower wall and connects the upper wall 16 and the lower wall 15. The circumferential wall 17 includes a front wall 21, a rear wall 22, a first side wall 23 (e.g., a left side wall), and a second side wall 24 (e.g., a right side wall).

As illustrated in FIG. 11, the housing 4 includes an upper cover 26 (i.e., a mask, a first cover, a first member, or a first component) and a lower cover 27 (i.e., a base, a second cover, a second member, or a second component).

The upper cover 26 and the lower cover 27 are combined to form an example of the housing 4. In the embodiment, the lower cover 27 is made from metal and has electrically conductive properties. On the other hand, the upper cover 26 is made from a synthetic resin. The upper cover 26 is a decorative member that covers the display 5 and is relatively thin. The upper cover 26 may be made from metal and may include the antenna cover 34 similarly to the second embodiment, for example.

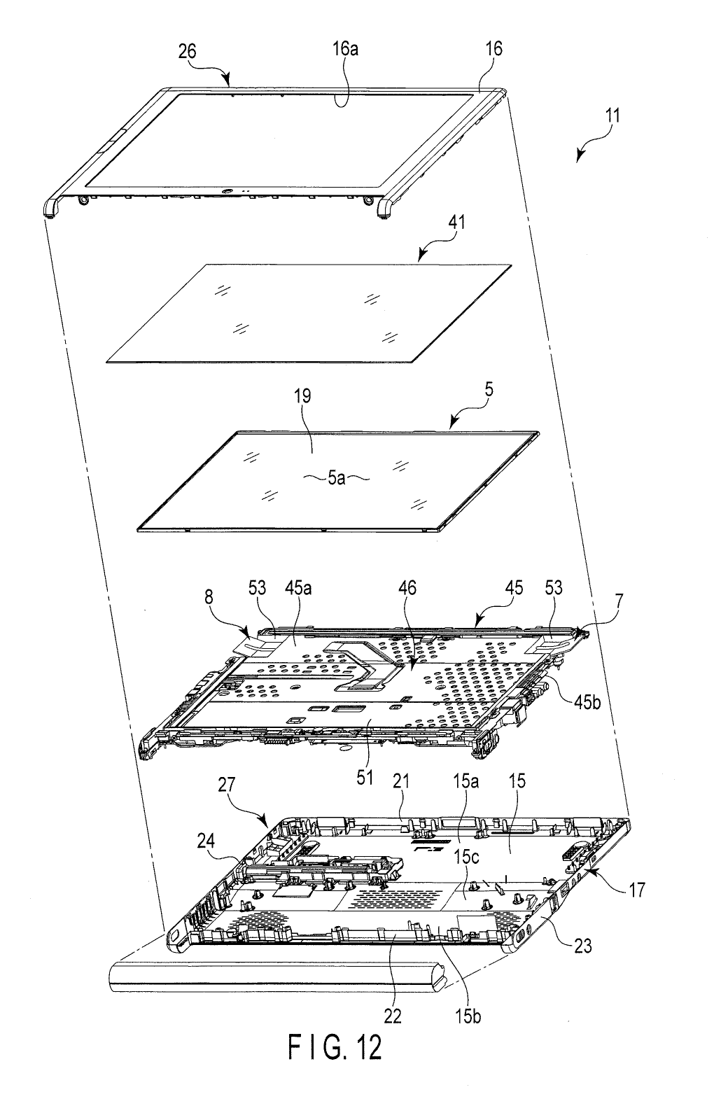

As illustrated in FIG. 12, a touch panel 41, the display 5, and a middle plate 45 (i.e., a middle base, a middle frame, an intermediate member, a plate portion, a reinforcing portion, or a reinforcing member) are provided between the upper cover 26 and the lower cover 27. The middle plate 45 is made from metal, for example, and has electrically conductive properties. The middle plate 45 is connected to the ground and has the ground potential. In the embodiment, the strength of the electronic apparatus 11 is secured by the middle plate 45 and the lower cover 27. The middle plate 45 may be made from a synthetic resin.

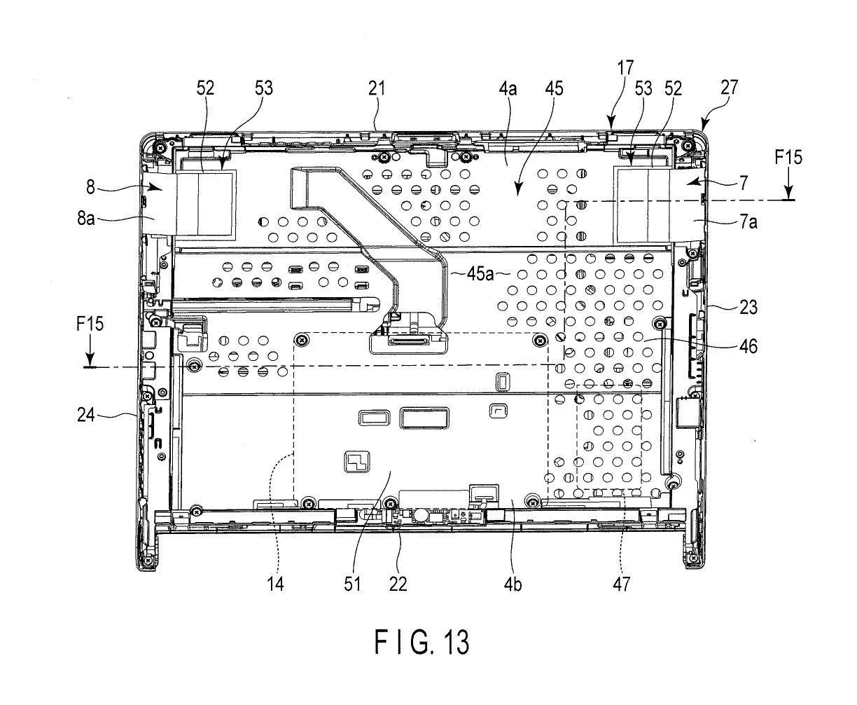

As illustrated in FIG. 13, the middle plate 45 extends over substantially the entire inner region of the housing 4, for example. The middle plate 45 extends between the front wall 21 and the rear wall 22. On the other hand, a gap (i.e., a region or a space portion) in which the element portion 7a of the first antenna 7 is positioned is formed between the middle plate 45 and the first side wall 23. Moreover, a gap (i.e., a region or a space portion) in which the element portion 8a of the second antenna 8 is positioned is formed between the middle plate 45 and the second side wall 24.

As illustrated in FIGS. 12 and 13, the middle plate 45 has a plate-like shape that is greater than the display 5, for example. A depression 46 (i.e., a recess) corresponding to the thickness of the display 5 is formed on the surface of the middle plate 45. The display 5 is attached to the depression 46 of the middle plate 45. The middle plate 45 covers the entire region of the back surface of the display 5 and supports the display 5.

As illustrated in FIG. 13, a first circuit board 14 and a second circuit board 47 are accommodated in the housing 4. The first circuit board 14 and the second circuit board 47 each are examples of a “component (i.e., member) that emits electromagnetic noise.” The “component (member) that emits electromagnetic noise” is not limited to the first circuit board 14 and the second circuit board 47 but appropriately includes various modules and electronic components that are accommodated in the housing 4.

The first circuit board 14 and the second circuit board 47 are positioned between the middle plate 45 and the lower wall 15. The first circuit board 14 is a main board, for example, and is electrically connected to the display 5. The first circuit board 14 and the second circuit board 47 are positioned closer to the second end portion 4b than to the first end portion 4a of the housing 4.

The first circuit board 14 and the second circuit board 47 are located at a position away from the first lower wall 15a and face the second lower wall 15b and the slope portion 15c. The first circuit board 14 is located substantially at the central portion of the housing 4, for example, in the longitudinal direction of the housing 4. The second circuit board 47 is located between the first circuit board 14 and the first side wall 23.

As illustrated in FIG. 13, the first antenna 7 and the second antenna 8 are accommodated in the housing 4. The first antenna 7 and the second antenna 8 are located at the first end portion 4a of the housing 4. The first antenna 7 and the second antenna 8 are provided at the left and right ends of the housing 4, respectively.

The first antenna 7 is positioned close to the first side wall 23. The second antenna 8 is positioned close to the second side wall 24. More specifically, the first antenna 7 is positioned at a first corner of the left front end portion of the housing 4. The second antenna 8 is positioned at a second corner of the right front end portion of the housing 4.

As illustrated in FIG. 13, the middle plate 45 faces the first circuit board 14, the second circuit board 47, the first antenna 7, and the second antenna 8 in the thickness direction of the housing 4. As an example of the middle plate 45 covers at least a portion of any one of the first circuit board 14 and the second circuit board 47 and covers at least a portion of the first antenna 7. In other words, the middle plate 45 extends between the first circuit board 14 and the first antenna 7 and extends between the second circuit board 47 and the first antenna 7.

Next, a shielding structure around the antennas 7 and 8 according to the embodiment will be described. In this example, the relationship between the first circuit board 14 and the first antenna 7 will be described as a representative example. The relationship between the second circuit board 47 and the first antenna 7 may be understood when the “first circuit board 14” in the following description is read the “second circuit board.” The relationship between the first circuit board 14 and the second antenna 8 may be understood when the “first antenna 7” in the following description is read the “second antenna 8.”

As illustrated in FIGS. 12 and 13, the middle plate 45 includes a first surface 45a and a second surface 45b. The first surface 45a is an upper surface, for example, and faces the upper cover 26. The depression 46 is formed on the first surface 45a, and the display 5 is attached to the first surface 45a. The second surface 45b is positioned on a side opposite to the first surface 45a. The second surface 45b is a lower surface, for example, and faces the lower cover 27.

As illustrated in FIGS. 12 and 13, in the embodiment, the first circuit board 14 (hereinafter referred to as the circuit board 14) and the first antenna 7 (hereinafter referred to as the antenna 7) are disposed on the upper and lower sides of the middle plate 45, respectively. Thus, the antenna 7 faces the first surface 45a of the middle plate 45. The circuit board 14 faces the second surface 45b of the middle plate 45.

As illustrated in FIGS. 12 to 15, the middle plate 45 includes a first region 51 that faces the circuit board 14 and a second region 52 that faces the antenna 7. The second region 52 includes a recess 53 (i.e., a depression or an attachment portion) that is depressed from the first region 51 so that the antenna 7 is attached to the recess 53.

The recess 53 includes a mounting wall 54 (i.e., a bottom wall, a supporting wall, or a first wall) and a standing wall 55 (an erected wall, a side wall, or a second wall). In the embodiment, the first region 51, the mounting wall 54, and the standing wall 55 have electrically conductive properties and are examples of a “shielding portion” and a “shield.” In addition, the first region 51, the mounting wall 54, and the standing wall 55 may be made from a synthetic resin and may have electrically conductive properties by means of metal coating, plating, or the like. The first region 51, the mounting wall 54, and the standing wall 55 as well as the upper cover 26 are connected to the ground and have the ground potential.

The mounting wall 54 extends substantially in parallel with the first wall 45a and expands substantially horizontally, for example. The mounting wall 54 is greater than the outer shape of the antenna 7. The antenna 7 is attached to the mounting wall 54 and fixed to the mounting wall 54.

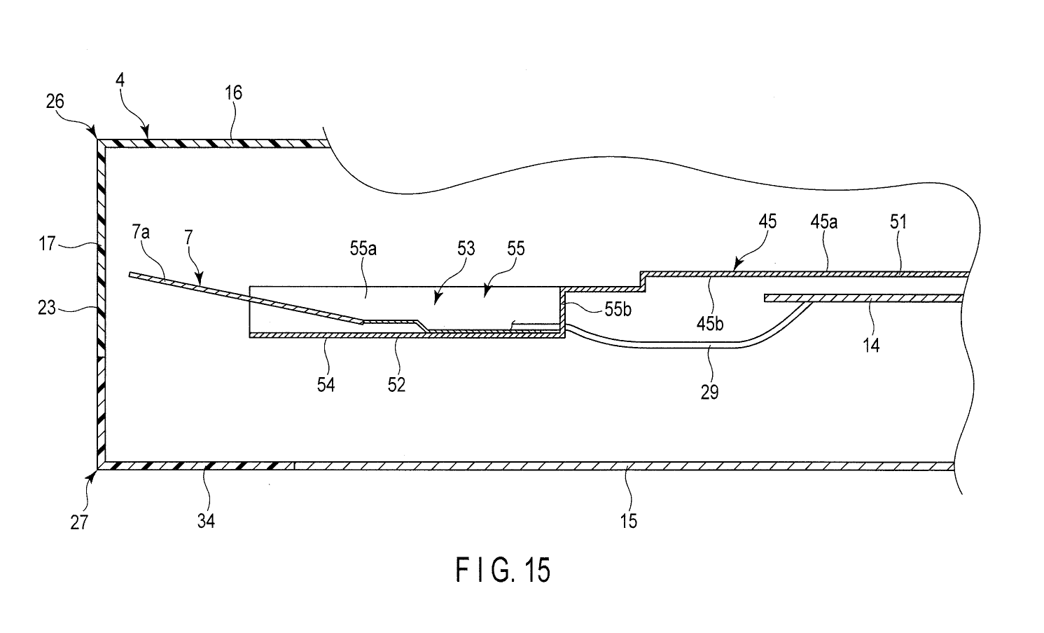

As illustrated in FIG. 15, a step is formed between the mounting wall 54 and the first region 51. The mounting wall 54 is closer to the lower wall 15 than the first region 51. In the embodiment, at least a portion (e.g., the entire portion) of the mounting wall 54 is closer to the lower wall 15 than the circuit board 14.

The standing wall 55 stands from an end portion (e.g., edge) of the mounting wall 54 and connects the mounting wall 54 and the first region 51. The standing wall 55 extends in a direction crossing (e.g., substantially orthogonal to) the mounting wall 54 and the first region 51. The standing wall 55 extends in the thickness direction of the housing 4, for example. As illustrated in FIG. 15, the standing wall 55 is positioned between the circuit board 14 and the antenna 7.

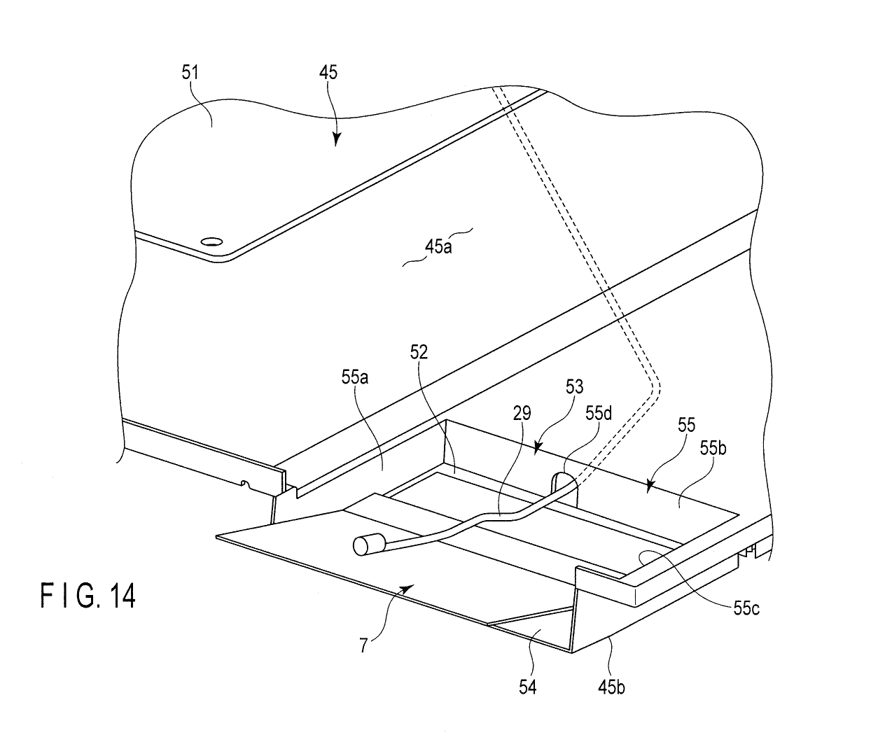

As illustrated in FIGS. 13 and 14, the standing wall 55 is provided along a portion of the outer shape of the antenna 7 and faces the antenna 7 from a plurality of directions (e.g., three directions). Specifically, the standing wall 55 includes a first portion 55a, a second portion 55b, and a third portion 55c.

The first portion 55a extends in the longitudinal direction of the housing 4. The first portion 55a faces the circuit board 14 and also faces the antenna 7. The first portion 55a is positioned between the circuit board 14 and the antenna 7. In other words, the circuit board 14 is positioned between the first portion 55a and the rear wall 22. The antenna 7 is positioned between the first portion 55a and the front wall 21.

The second portion 55b extends in a direction crossing (e.g., substantially orthogonal to) the first portion 55a. The second portion 55b does not face the circuit board 14. The second portion 55b faces the antenna 7 from a side opposite to the first side wall 23. In other words, the antenna 7 is positioned between the second portion 55b and the first side wall 23.

A guiding portion 55d (i.e., pass) through which the cable 29 passes is provided on the second portion 55b. The guiding portion 55d is open in a direction where the guiding portion 55d does not face the circuit board 14 (i.e., a component that emits electromagnetic noise). An example of the guiding portion 55d is a hole (a through hole). The guiding portion 55d may be a slit or a cut-out.

The third portion 55c extends substantially in parallel with the first portion 55a. The third portion 55c faces the antenna 7 from a side opposite to the first portion 55a. In other words, the antenna 7 is positioned between the first portion 55a and the third portion 55c. With the above-described configuration, the standing wall 55 faces the antenna 7 from three directions. The antenna 7 transmits and receives electromagnetic waves from the remaining one direction. In other words, at least a portion of the antenna 7 is accommodated in the recess 53 that is formed by the mounting wall 54 and the standing wall 55.

Similarly to the second embodiment, an end portion of the lower cover 27 includes an antenna cover 35. The antenna cover 35 is made from a synthetic resin and faces element portions 7a and 8a of the antennas 7 and 8. The antennas 7 and 8 transmit and receive electromagnetic waves to and from the outside through the antenna cover 35.

According to such a configuration, it is possible to improve the usability of the electronic apparatus 11 similarly to the second embodiment. For example, in the embodiment, the electronic apparatus includes a component (e.g., the circuit board 14) that emits electromagnetic noise, the antenna 7 that is accommodated in the housing 4, and a conductive member (e.g., the middle plate 45) that includes a wall (e.g., the standing wall 55) that is disposed between the component and the antenna 7 so as to extend in the thickness direction of the housing 4, and is accommodated in the housing 4 so as to cover at least a portion of the component and at least a portion of the antenna 7.

According to such a configuration, since part of the electromagnetic noise propagating from the component toward the antenna 7 is blocked by the wall, it is possible to suppress a decrease of the performance of the antenna 7. In this way, it is possible to provide a shielding structure that does not use a gasket. In this way, since the product quality is improved, and rattling of legs, for example, does not occur, the usability of the electronic apparatus is improved. Further, similarly to the second embodiment, it is possible to decrease the product cost, increase the efficiency of the assembling operation, and stabilize the antenna performance.

In the embodiment, the member includes the first surface 45a and the second surface 45b that is positioned on a side opposite to the first surface 45a. The antenna 7 faces the first surface 45a. The component faces the second surface 45b. That is, in the embodiment, the component and the antenna 7 are mounted on the upper and lower sides of the member, respectively. In this way, the member itself constitutes a portion of the shielding structure, and the antenna performance can be further stabilized.

In the embodiment, the member includes the first region 51 that makes contact with the component and the second region 52 that is depressed in relation to the first region 51 so that the antenna 7 is attached to the second region 52. According to such a configuration, even when the component and the antenna 7 are mounted on the front and rear sides of the member, respectively, it is possible to suppress the thickness of the housing 4 from increasing.

In the embodiment, the wall extends along a portion of the outer shape of the antenna 7 and faces the antenna 7 from three directions. According to such a configuration, it is possible to further stabilize the antenna performance.

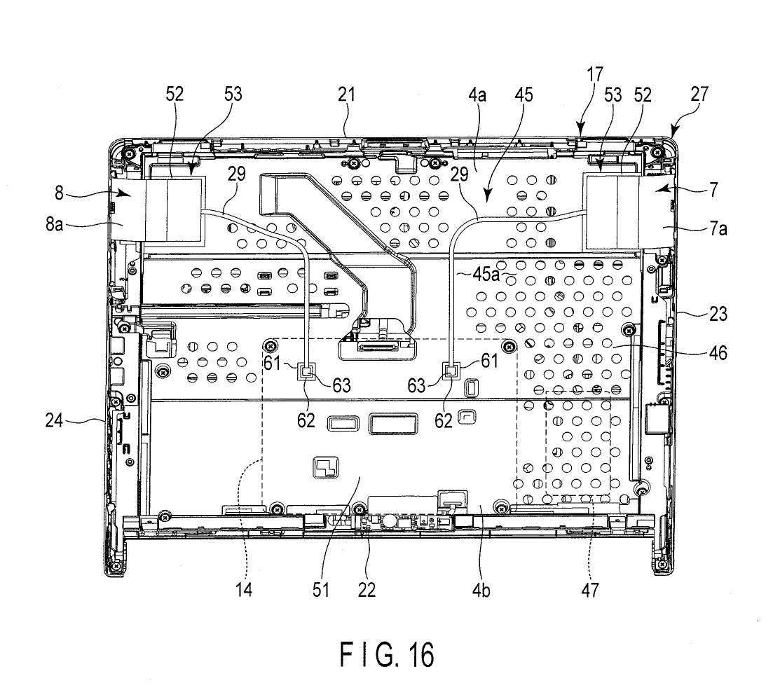

Next, a modification of the embodiment will be described with reference to FIG. 16.

As illustrated in FIG. 16, in this modification, an opening 61 is formed in the middle plate 45. A first connector 62 is mounted on the circuit board 14. The opening 61 is provided at the position corresponding to the first connector 62. The first connector 62 is exposed through the opening 61.

The cable 29 includes a second connector 63 at the distal end of the cable 29. The second connector 63 engages with the first connector 62 and is electrically connected to the circuit board 14 via the first connector 62. The second connector 63 can engage with the first connector 61 from the thickness direction of the housing 4.

According to such a configuration, the cable 29 of the antenna 7 provided on the upper side of the middle plate 45 can be easily electrically connected to the circuit board 14 that is positioned on the lower side of the middle plate 45. In this way, it is possible to improve the assembling workability of the electronic apparatus 11.

The embodiments are not limited to the embodiments described above but may be realized by modifying constituent elements in the implementing step within a range without departing from the spirit of the invention. Moreover, various embodiments can be made by appropriately combining a plurality of constituent elements disclosed in the embodiments described above. For example, some constituent elements may be omitted from all constituent elements disclosed in the embodiments. Furthermore, constituent elements in different embodiments may be combined appropriately.

For example, any one of the first rib 31 and the second rib 32 may be not provided. The first rib 31, the second rib 32, and the standing wall 55 are not limited to facing the antenna 7 from three directions but may face the antenna 7 from one direction or two directions, for example. The middle plate 45 may be not provided with the recess 53. That is, the circuit board 14 and the antenna 7 may be respectively provided on the front and rear sides of the middle plate 45 that does not have the recess 53.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television comprising:
a housing;
a component in the housing, the component configured to emit electromagnetic noise;
an antenna in the housing;
a first electrically conductive rib in the housing, the first rib projecting in a thickness direction of the housing between the component and the antenna; and
a second electrically conductive rib projecting in the thickness direction of the housing from an inner surface of the housing, the second rib between the component and the first rib or between the first rib and the antenna.

2. The television of claim 1, wherein
the first rib comprises a first pass, and
the antenna comprises a cable extending through the first pass of the first rib.

3. The television of claim 2, wherein
the first rib further comprises a first portion between the component and the antenna and a second portion comprising the first pass, the second portion extending in a direction crossing the first portion, and the second portion not facing the component.

4. The television of claim 2, wherein
the second rib comprises a second pass through which the cable extends, and
the first pass and the second pass are at positions offset from each other.

5. The television of claim 4, wherein
the cable is set in the first pass after the cable is set in the second pass and connected to the housing, and
a width of the first pass is greater than a width of the second pass.

6. The television of claim 1, wherein the first rib is a portion of the housing.

7. The television of claim 1, further comprising a member in the housing, the member over at least a portion of the component and at least a portion of the antenna, and wherein the first rib is a portion of the member.

8. An electronic apparatus comprising:
a housing;
a component in the housing, the component configured to emit electromagnetic noise;
an antenna in the housing; and
an electrically conductive member over at least a portion of the component and at least a portion of the antenna in the housing, the member comprising a wall between the component and the antenna, the wall projecting in a thickness direction of the housing.

9. The electronic apparatus of claim 8, wherein
the member comprises a first surface and a second surface opposite the first surface,
the antenna faces the first surface, and
the component faces the second surface.

10. The electronic apparatus of claim 8, wherein
the member further comprises a first region facing the component and a second region comprising a depression from the first region, the antenna on the second region.

11. The electronic apparatus of claim 8, wherein
the wall is along a portion of the antenna and faces the antenna from three directions.

12. An electronic apparatus comprising:
a housing;
a component in the housing, the component configured to emit electromagnetic noise;
an antenna in the housing; and
an electrically conductive wall in the housing, the wall between the component and the antenna.

13. The electronic apparatus of claim 12, wherein the wall is a portion of the housing.

14. The electronic apparatus of claim 12, further comprising a member in the housing, the member facing the component in a thickness direction of the housing, and wherein the wall is a portion of the housing.
